(19) United States
(12) Patent Application Publication
(10) Pub. No.: US 2009/0114962 A1
(43) Pub. Date: May 7, 2009

(54) Image Sensor and Method for Manufacturing Thereof

(76) Inventor: Ji Hwan Park, Chungju-si (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/256,514

(22) Filed: Oct. 23, 2008

(30) Foreign Application Priority Data
Nov. 1, 2007 (KR) 10-2007-0110761

(51) Int. Cl. H01L 31/00; H01L 21/00

(52) U.S. Cl. 257/292; 438/57; 257/E21.001; 257/E31.001

(57) ABSTRACT

Disclosed are an image sensor and a method for manufacturing the same. The image sensor can include a first pixel including a first photodiode and a first gate; a second pixel adjacent the first pixel and including a second photodiode and a second gate; and a barrier layer between the first photodiode and the second photodiode. The barrier layer can be formed by implanting ions into a semiconductor substrate at a region between adjacent photodiodes. A shallow trench isolation (STI) can be omitted in the regions between adjacent photodiodes by using the ion-implanted barrier layer to isolate the photodiodes from each other.

### CROSS-REFERENCE TO RELATED APPLICATION

The present application claims the benefit under 35 U.S.C. §119 of Korean Patent Application No. 10-2007-0110761, filed Nov. 1, 2007, which is hereby incorporated by reference in its entirety.

### BACKGROUND

Image sensors are semiconductor devices for converting an optical image into an electrical signal, and are generally classified as charge coupled device (CCD) image sensors or complementary metal oxide semiconductor (CMOS) image sensors.

The CMOS image sensor includes a photodiode and a MOS transistor in each unit pixel, and sequentially detects the electric signals of each unit pixel through the MOS transistor in a switching mode to realize images.

### BRIEF SUMMARY

Embodiments of the present invention provide an image sensor and a method for manufacturing the same.

According to an embodiment, an image sensor can comprise a first pixel including a first photodiode and a first gate; a second pixel adjacent the first pixel and including a second photodiode and a second gate; and a barrier layer between the first photodiode and the second photodiode. The barrier layer can be an ion implantation layer isolating the photodiodes of adjacent pixels.

According to another embodiment, a method for manufacturing an image sensor can comprise forming a barrier layer, a first photodiode and a second photodiode in a semiconductor substrate, where the barrier layer separates the first photodiode from the second photodiode; forming a gate on the semiconductor substrate; and forming a metal interconnection layer on the semiconductor substrate including the gate. According to embodiments, the barrier layer can be formed by implanting impurities into the semiconductor substrate in a region between the first photodiode and the second photodiode. In addition, the barrier layer can be used in defining a boundary between the first photodiode and the second photodiode.

### BRIEF DESCRIPTION OF THE DRAWINGS

FIG. 1 is a plan view of an image sensor according to an embodiment of the present invention.

FIGS. 2 to 10 are sectional views taken along line A-A′ of FIG. 1 and illustrate a method for manufacturing an image sensor according to an embodiment of the present invention.

FIG. 11 is a plan view of an image sensor according to another embodiment.

FIG. 12 is a cross-sectional view taken along line B-B′ of FIG. 11 according to an embodiment of the present invention.

### DETAILED DESCRIPTION

Hereinafter, embodiments of an image sensor and a method for manufacturing the same will be described in detail with reference to accompanying drawings.

In the description of an embodiment, it will be understood that, when a layer is referred to as being “on/under” another layer or substrate, it can be directly on/under the other layer or substrate, or one or more intervening layers may also be present.

Although the present embodiment has been described with reference to drawings showing a CIS (CMOS Image Sensor), the present invention is not limited to the CIS. For example, the present invention is applicable for various image sensors including a CCD image sensor.

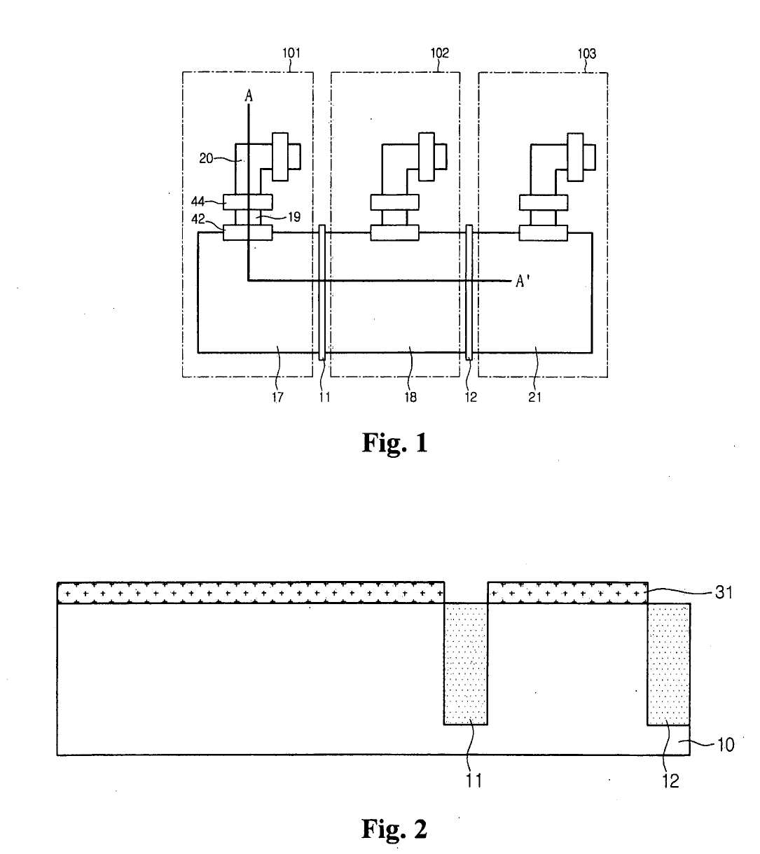

FIG. 1 is a plan view of an image sensor according to an embodiment.

Referring to FIG. 1, an image sensor can include a plurality of pixels including a first pixel 101, a second pixel 102 and a third pixel 103.

Each of the first pixel 101, the second pixel 102 and the third pixel 103 includes a photodiode and at least one transistor.

A first barrier 11 can be provided between a first photodiode 17 formed in the first pixel 101 and a second photodiode 18 formed in the second pixel 102.

In addition, a second barrier 12 can be provided between the second photodiode 18 formed in the second pixel 102 and a third photodiode 21 formed in the third pixel 103.

The first barrier 11 and the second barrier 12 can be ion implantation layers doped with p-type impurities. In addition, the first barrier 11 and the second barrier 12 can be formed to have a depth deeper than a depth of the first photodiode 17, the second photodiode 18 and the third photodiode 21. For example, the first barrier 11 and the second barrier 12 can be formed to have a depth of 1000 to 1500 Å.

Since the first barrier 11 and the second barrier 12 can be formed through the ion implantation without forming an STI (Shallow Trench Isolation), damage generated by STI formation can be minimized.

That is, according to the image sensor of the an embodiment, the barrier provided in the form of the ion implantation layer can be formed between the photodiodes instead of an STI, thereby minimizing leakage current generated by a dislocation of the STI.

Although three pixels are described with respect to the present embodiment, it should not be construed as limiting the image sensor to having three pixels.

A method for manufacturing an image sensor according to an embodiment will be described with reference to FIGS. 2 to 10, which provide cross-sectional views taken along line A-A′ of FIG. 1.

Referring to FIG. 2, barriers including a first barrier 11 and a second barrier 12 can be formed in a first semiconductor substrate 10.

According to embodiments, the first semiconductor substrate 10 can include a lightly doped p type epitaxial layer on a heavily doped p++ type silicon substrate.

Therefore, due to the existence of the lightly doped p type epitaxial layer, a depletion region of the photodiodes can be enlarged and deepened, so that the ability of the photodiodes to collect photo charges can be improved.

In addition, if the heavily doped p++ type substrate is provided below the p-type epitaxial layer, recombination of charges may occur before the charges are diffused to an adjacent unit pixel. Accordingly, random diffusion of the photo charges is reduced, so that the transfer function of the photo charges is inhibited from being changed.

Although not shown, an isolation layer can be formed in the first semiconductor substrate to define active regions. However, in accordance with embodiments of the present invention, the isolation layer is omitted for certain regions between adjacent photodiodes.

According to an embodiment, to form the first barrier 11 and the second barrier 12, a first photoresist pattern 31 can be formed on the first semiconductor substrate 10 and then a first ion implantation process can be performed using the first photoresist pattern 31 as an implantation mask.

The first ion implantation process can be performed by implanting p type ion impurities into the semiconductor substrate 10. The barriers (11 and 12) can be formed to a depth such that the first and second barriers 11 and 12 are deeper than the photodiodes to be formed later. In one embodiment, first barrier 11 and the second barrier 12 can be formed to a depth of about 1000 Å to 1500 Å.

The first ion implantation process can be performed under the condition of 5×10¹²˜1×10¹³ atoms/cm² dose of ¹¹B⁺ions and ion implantation energy of 20˜100 KeV.

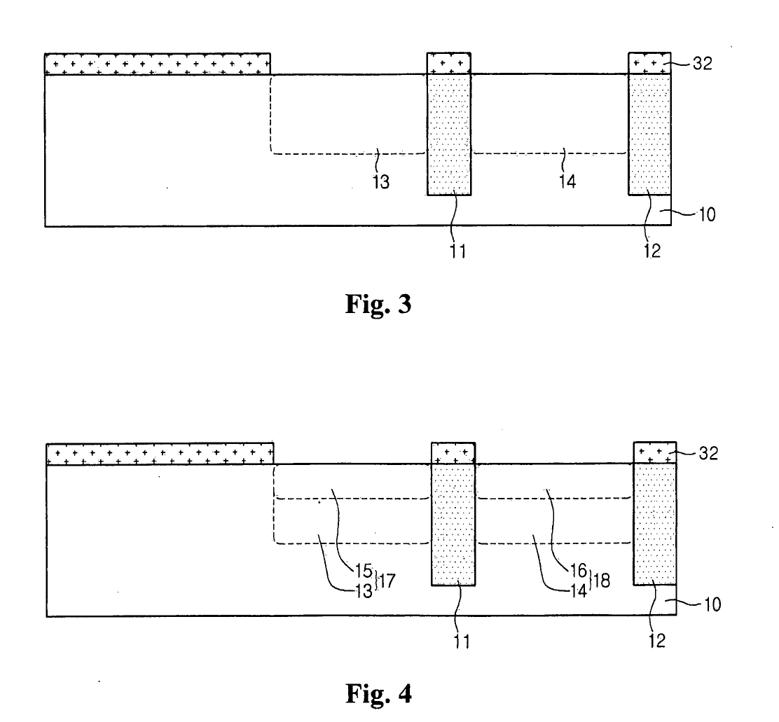

Referring to FIG. 3, a first impurity region 13 and a second impurity region 14 can be formed on the first semiconductor substrate 10.

The first impurity region 13 and the second impurity region 14 can be formed by forming a second photoresist pattern 32 on the first semiconductor substrate 10 and then performing a second ion implantation process using n type impurities.

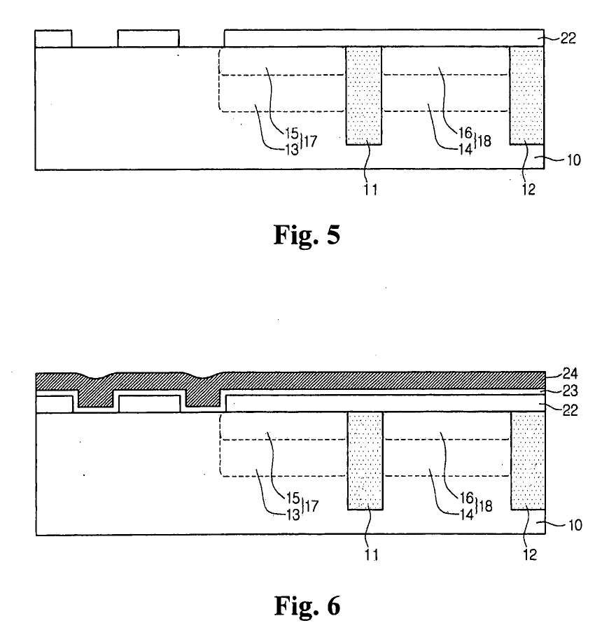

Then, referring to FIG. 4, a third impurity region 15 and a fourth impurity region 16 can be formed on the first semiconductor substrate 10.

The third impurity region 15 and the fourth impurity region 16 can be formed by performing a third ion implantation process, in which p type impurities are implanted using the second photoresist pattern 32 as a mask.

Accordingly, the first photodiode 17 can include the first impurity region and the third impurity region 15 and the second photodiode 18 can include the fourth impurity region 16.

The first photodiode 17 and the second photodiode 18 are formed in a depth shallower than the first barrier 11 and the second barrier 12.

That is, the first barrier 11 and the second barrier 12 are formed to a depth deeper than the first photodiode 17 and the second photodiode 18, thereby electrically isolating the first photodiode 17 from the second photodiode 18.

According to embodiments of the subject image sensor, the photodiodes can be isolated from each other by the barrier formed through the ion implantation, so that the occurrence of leakage current is minimized as compared with an image sensor in which photodiodes are isolated by an STI.

According to the present embodiment, after the first barrier 11 and the second barrier 12 have been formed, the first photodiode 17 and the second photodiode 18 are formed. However, the order of process steps is not limited to such an embodiment. For example, according to another embodiment, the first photodiode 17 and the second photodiode 18 can be formed first, and then the first barrier 11 and the second barrier 12 can be formed.

Referring to FIG. 5, a first oxide layer pattern 22 can be formed on the first semiconductor substrate 10.

According to an embodiment, the first oxide layer pattern 22 can be formed by depositing and patterning an oxide layer. The first oxide layer pattern 22 can be formed to expose regions of the substrate upon which gate electrodes are to be formed. In an embodiment, first oxide layer pattern 22 can be formed with a thickness of about 1000 to 2000 Å. In one embodiment, the first oxide layer pattern 22 can be formed of tetraethyl orthosilicate (TEOS).

The TEOS layer serving as the first oxide layer can be patterned by performing a dry etching process.

After that, referring to FIG. 6, a second oxide layer 23 and a polysilicon layer 24 can be formed on the first semiconductor substrate 10 including the first oxide layer pattern 22.

The second oxide layer 23 and the polysilicon layer 24 can be provided to form the gate of a transistor.

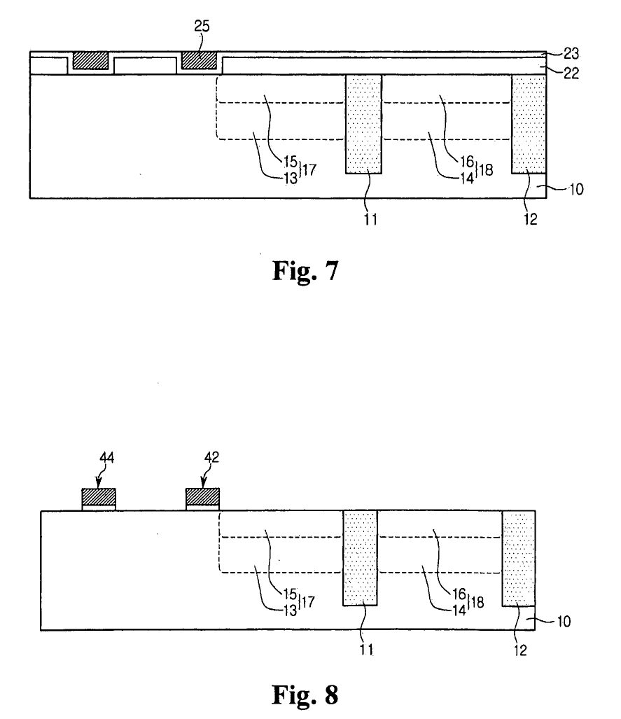

Referring to FIG. 7, a planarization process can be performed on the polysilicon layer 24 to form a polysilicon pattern 25.

Referring to FIG. 8, the first oxide layer pattern 22 can be removed such that a first gate 42 and a second gate 44 are formed on the first semiconductor substrate 10.

The first gate 42 and the second gate 44 can be formed by removing a part of the second oxide layer 23 and the first oxide layer pattern 22 from the first semiconductor substrate 10.

According to embodiments, after the first barrier 11, the second barrier 12, the first photodiode 17 and the second photodiode 18 have been formed, the first gate 42 and the second gate 44 can be formed.

However, the process order is not limited thereto. For example, according to another embodiment, after the first gate 42 and the second gate 44 have been formed, the first barrier 1, the second barrier 12, the first photodiode 17 and the second photodiode 18 can be formed.

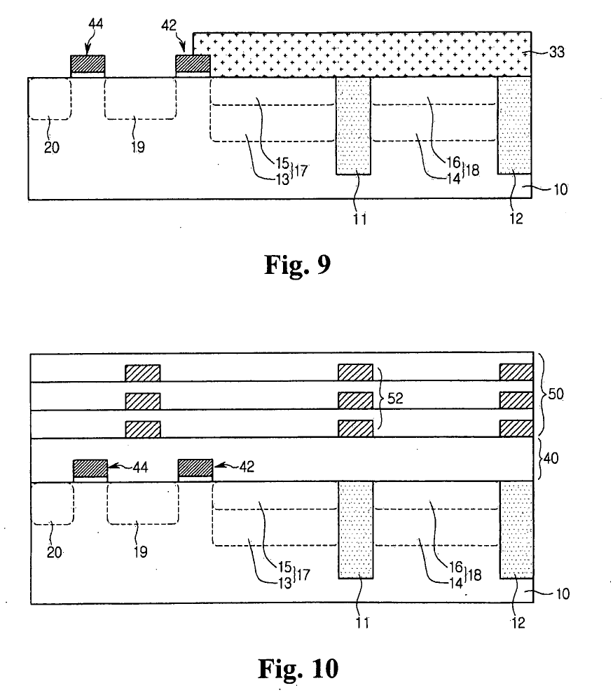

Referring to FIG. 9, a fifth impurity region 19 and a sixth impurity region 20 can be formed on the first semiconductor substrate 10 including the first gate 42 and the second gate 44.

The fifth impurity region 19 and the sixth impurity region 20 can be formed by forming a third photoresist pattern 33 on the first semiconductor substrate 10 and then performing a fourth ion implantation process.

The fifth impurity region 19 can serve as a diffusion region.

Referring to FIG. 10, an insulating layer can be formed on the first semiconductor substrate 10 to insulate the circuit layer 40 and then a metal interconnection layer 50 including a metal interconnection 52 can be formed on the circuit layer 40.

Although not shown in the drawings, in certain embodiments, a color filter array and a micro-lens can be formed on the metal interconnection layer 50.

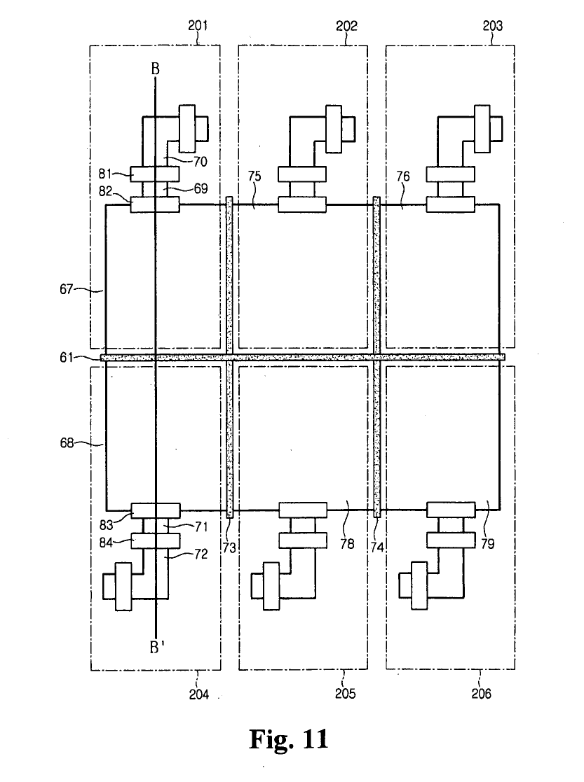

FIG. 11 is a plan view of an image sensor according to an embodiment.

As shown in FIG. 11, an image sensor can include pixels that are symmetric about an axis. For example, a first pixel 201, a second pixel 202, and a third pixel 203 can be arranged in a first row, and a fourth pixel 204, a fifth pixel 205 and a sixth pixel 206 can be arranged in a second row having rotational symmetry with the first row.

Each pixel (201, 202, 203, 204, 205 and 206) can include a corresponding photodiode (67, 75, 76, 68, 78 and 79). According to embodiments, the pixels (201, 202, 203, 204, 205 and 206) are arranged such that their corresponding photodiodes (201, 202, 203, 204, 205 and 206) are disposed together.

The first, second, and third photodiodes 67, 75 and 76 can be isolated from the fourth, fifth and sixth photodiodes 68, 78 and 79 by a third barrier 61.

A first barrier 73 can be used to isolate the first photodiode 67 from the second photodiode 75, and the fourth photodiode 68 from the fifth photodiode 78. A second barrier 74 can be used to isolate the second photodiode 75 from the third photodiode 76, and the fifth photodiode 78 from the sixth photodiode 79.

The third barrier 61, the first barrier 73 and the second barrier 74 can be an ion implantation layer doped with p type impurities, and formed to have a depth such as about 1000 to 1500 Å, which is deeper than the depth of the photodiodes 67, 75, 76, 68, 78 and 79.

Since the third barrier 61, the first barrier 73 and the second barrier 74 are formed through ion implantation without forming an STI between the first, second, third, fourth, fifth, and sixth photodiodes 67, 75, 76, 68, 78 and 79, damage generated by STI formation can be minimized.

That is, according to embodiments of the present invention, a barrier provided in the form of an ion implantation layer can be formed between the photodiodes, thereby minimizing leakage current caused by dislocation of an STI.

Although the present embodiment has been described in that the image sensor includes six pixels, the present invention is not limited thereto, and can include more than six pixels.

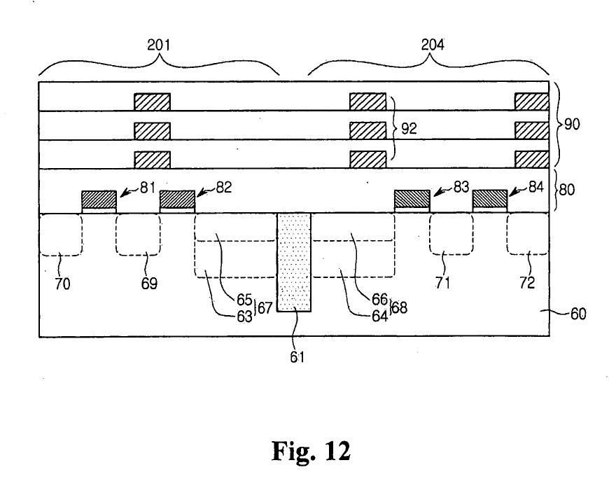

FIG. 12 is a sectional view taken along line B-B′ of FIG. 11.

Referring to FIG. 11, the first pixel 201 and the fourth pixel 204 are illustrated.

The first pixel 201 can include a first photodiode 67 and n-type diffusion regions 69 and 70 formed in a second semiconductor substrate 60, a first gate 81 and a second gate 82. In an embodiment, the first photodiode 67 can include an n-type impurity region 63 and a p-type impurity region 65.

In addition, the fourth pixel 204 can include a fourth photodiode 68 and n-type impurity regions 71 and 72 formed in the semiconductor substrate 60, a third gate 83 and a fourth gate 84. In an embodiment, the fourth photodiode 68 can include an n-type impurity region 64 and a p-type impurity region 66.

An insulating layer can be formed on the second semiconductor substrate 60 including the first gate 81, the second gate 82, the third gate 83 and the fourth gate 84 such that a circuit layer 80 is formed. A metal interconnection layer 90 including a metal interconnection 92 can be formed on the circuit layer 80.

The image sensor shown in FIG. 12 can be manufactured in accordance with the embodiments described with reference to FIGS. 2-10.

According to embodiments of the image sensor and the method of manufacturing the same, the barrier provided in the form of the ion implantation layer is formed between the photodiodes instead of an STI, so that leakage current caused by dislocation of the STI can be minimized and reliability of the device can be improved.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for manufacturing an image sensor, the method comprising:
implanting ions into a semiconductor substrate to form a barrier layer in a semiconductor substrate;
forming a first photodiode and a second photodiode adjacent the first photodiode in the semiconductor substrate, wherein the barrier layer is disposed in a region of the semiconductor substrate between the first photodiode and the second photodiode;
forming a gate on the semiconductor substrate; and
forming a metal interconnection layer on the semiconductor substrate including the gate;

2. The method according to claim 1, wherein the barrier layer is disposed between the first photodiode and the second photodiode such that the barrier layer isolates the first photodiode from the second photodiode and isolates the first photodiode and the second photodiode from any other photodiode adjacent to the first photodiode or the second photodiode.

3. The method according to claim 1, wherein the first photodiode and the second photodiode are formed after implanting the ions into the semiconductor substrate to form the barrier layer.

4. The method according to claim 1, wherein the first photodiode and the second photodiode are formed before implanting the ions into the semiconductor substrate to form the barrier layer.

5. The method according to claim 1, wherein the barrier layer is formed to a depth deeper than a depth of the first photodiode and the second photodiode.

6. The method according to claim 5, wherein the barrier layer is formed to a depth of about 1000 to 1500 Å.

7. The method according to claim 1, wherein implanting ions into the semiconductor substrate to form the barrier layer comprises implanting p type impurities into the semiconductor substrate.

8. The method according to claim 7, wherein implanting the p type impurities into the semiconductor substrate comprises implanting a dose of 5×10¹²˜1×10¹³ atoms/cm² of ¹¹B⁺ions at an implantation energy of 20 to 100 KeV.

9. An image sensor comprising:
a first pixel comprising a first photodiode and a first gate:
a second pixel adjacent the first pixel and comprising a second photodiode and a second gate; and
an ion implanted barrier layer between the first photodiode and the second photodiode.

10. The image sensor according to claim 9, wherein the barrier layer comprises p type impurities.

11. The image sensor according to claim 9, wherein the barrier layer has a depth deeper than a depth of the first photodiode and the second photodiode.

12. The image sensor according to claim 11, wherein the barrier layer has a depth of about 1000 to 1500 Å.

13. The image sensor according to claim 9, further comprising:
a third pixel adjacent the first pixel and comprising a third photodiode and a third gate; and
a fourth pixel adjacent the third pixel and the second pixel and comprising a fourth photodiode and a fourth gate,
wherein the barrier layer is further disposed between the first photodiode and the third photodiode, the third photodiode and the fourth photodiode, and the fourth photodiode and the second photodiode.

14. The image sensor according to claim 13, wherein the first photodiode, the second photodiode, the third photodiode, and the fourth photodiode are isolated from each other by the barrier layer.
